(19) United States
(12) Patent Application Publication
(10) Pub. No.: US 2009/0091933 A1
(43) Pub. Date: Apr. 9, 2009

(54) KEYPAD ASSEMBLY AND PORTABLE ELECTRONIC DEVICE USING THE SAME

(75) Inventors: YUNG-CHANG YEN, Shindian (TW); CHIH-CHIANG CHANG, Shindian (TW)

Correspondence Address: PCE INDUSTRY, INC.;ATT. Steven Reiss, 458 E. LAMBERT ROAD, FULLERTON, CA, 92835, US

(73) Assignee: SUTECH TRADING LIMITED, Tortola (VG)

(21) Appl. No.: 11/961,325

(22) Filed: Dec. 20, 2007

(30) Foreign Application Priority Data
Oct. 9, 2007 (CN) 200710201953.4

(51) Int. Cl. F21V 33/00; H01H 13/704; H01H 13/72; H05K 5/02

(52) U.S. Cl. 362/253; 200/5 A

(57) ABSTRACT

A keypad assembly (20) for use in a portable electronic device (200) is provided. The keypad assembly includes a keypad (205), a light-guiding board (203), at least one light-emitting source (204), a light-shielding member (202). The keypad includes a first peripheral wall. The at least one light-emitting source is disposed proximate to a second peripheral sidewall (2031) of the light-guiding board and respectively aligned with the light-guiding board. The light-shielding member includes a main portion (2021) and at least one extending portion (2022) extending from the main portion. The at least one extending portion is configured for shielding light emitted from the at least one light-emitting source diffusing toward the first peripheral wall.

### BACKGROUND OF THE INVENTION

1. Field of the Invention

The present invention relates to keypad assemblies, particularly to a keypad assembly incorporating a light-shielding member and a portable electronic device using the keypad assembly.

2. Description of Related Art

With development of technology, portable electronic device (e.g., mobile phone or personal digital handset) has been developing more and more user-friendly functions therewith, e.g., the keypad assembly with illuminating effect, and etc.

With respect to that illuminating function of the keypad, which is convenient for users to operate in darkness even, the keypad assembly typically has a light-emitting source (e.g., light-emitting diode) assembled therewith. The light-emitting source can emit light for the keypad assembly in case of, for example, pressing any one key button of the keypad assembly.

The typical keypad assembly often has the light-emitting source disposed on a bottom end of a light-guiding board of the keypad assembly adjacent to a shell of the portable electronic device. In use, the light emitted from the light-emitting source illuminate the keypad assembly. However, some emitted light cannot be guided by the light-guiding board to penetrate through the shell. The effect of the shell illumination becomes more apparent in darkness, which may make users feel uncomfortable. Even the illumining effect could make the shell become dazzling and thus bother users in operating the keypad.

Therefore, a heretofore-unaddressed need exists in the art to address the aforementioned deficiencies and inadequacies.

### SUMMARY

In present aspect, a keypad assembly for use in a portable electronic device is provided. The keypad assembly includes a keypad, a light-guiding board, at least one light-emitting source, and a light-shielding member. The keypad includes a first peripheral wall. The light-guiding board includes a second peripheral wall and the second peripheral wall corresponds with the first peripheral wall. The at least one light-emitting source is disposed proximate to the second peripheral wall of the light-guiding board and respectively aligned with the light-guiding board. The light-shielding member is disposed between the keypad and the light-guiding board. The light-shielding member includes a main portion and at least one extending portion. The at least one extending portion extends from the main portion. The main portion is configured for allowing light emitted from the light-emitting source to penetrate through the light-guiding board to illuminate the keypad assembly. The at least one extending portion is configured for shielding light emitted from the at least one light-emitting source diffusing toward the first peripheral wall.

In another aspect, a portable electronic device using the present keypad assembly is provided. The portable electronic device further includes a housing. The keypad assembly is assembled with the housing.

These and other aspects of the present invention will become more apparent from the following detailed description of the preferred embodiments taken in conjunction with the accompanying drawings, although variations and modifications therein may be affected without departing from the spirit and scope of the novel concepts of the disclosure.

### BRIEF DESCRIPTION OF THE DRAWINGS

Many aspects of the present keypad assembly and portable electronic device can be better understood with reference to the following drawings. These drawings are not necessarily drawn to scale, the emphasis instead being placed upon clearly illustrating the principles of the present keypad assembly and portable electronic device. Moreover, in the drawings like reference numerals designate corresponding parts throughout the several views. Wherever possible, the same reference numbers are used throughout the drawings to refer to the same or like elements of an embodiment.

FIG. 1 is a partial top view of a portable electronic device using a keypad assembly in accordance with a present embodiment.

FIG. 2 is an isometric and exploded view of the keypad assembly shown in FIG. 1, showing one aspect thereof.

FIG. 3 is an isometric and exploded view of the keypad assembly shown in FIG. 1, showing another aspect thereof.

FIG. 4 is an assembled view of the keypad assembly shown in FIG. 2.

FIG. 5 is a cut-away view of the keypad assembly shown in FIG. 4, taken along line V-V.

### DETAILED DESCRIPTION OF THE EMBODIMENTS

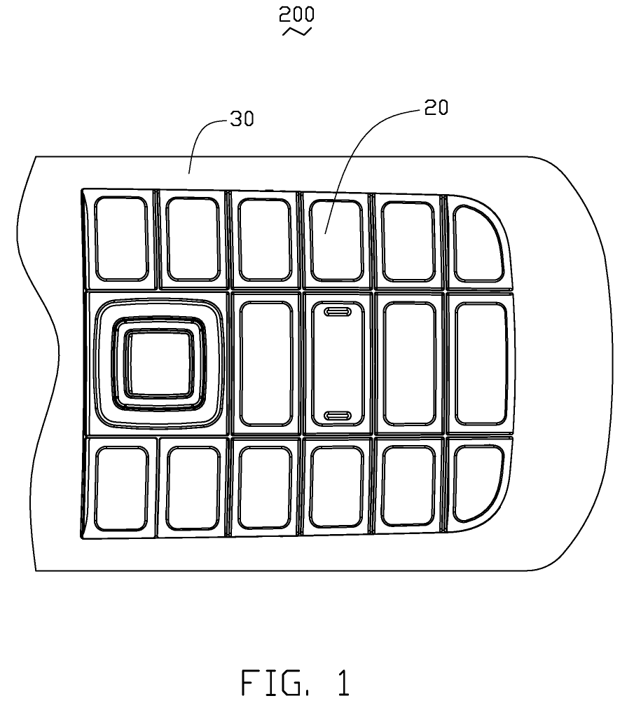

The present keypad assembly and portable electronic device using the keypad assembly are described here in conjunction with the accompanying drawings in FIGS. 1 through 5. The keypad assembly is suitably assembled within the portable electronic device, such as the mobile phone, the personal digital handset, or the like.

Referring to FIG. 1, the portable electronic device 200 includes a keypad assembly 20 and a housing 30. The keypad assembly 20 is assembled with the housing 30.

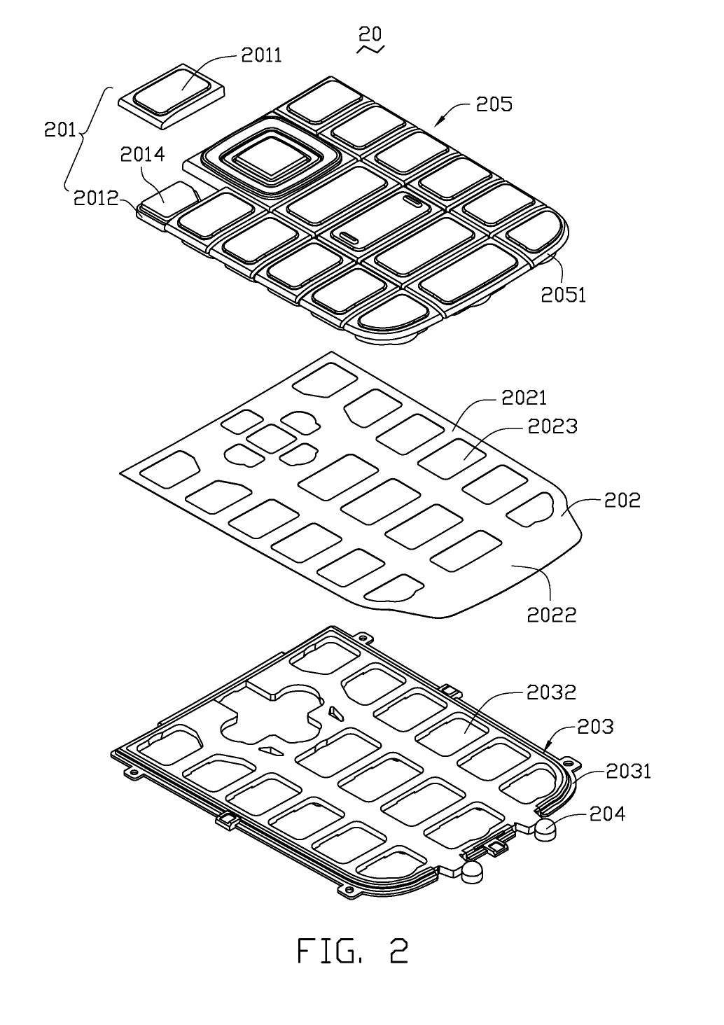

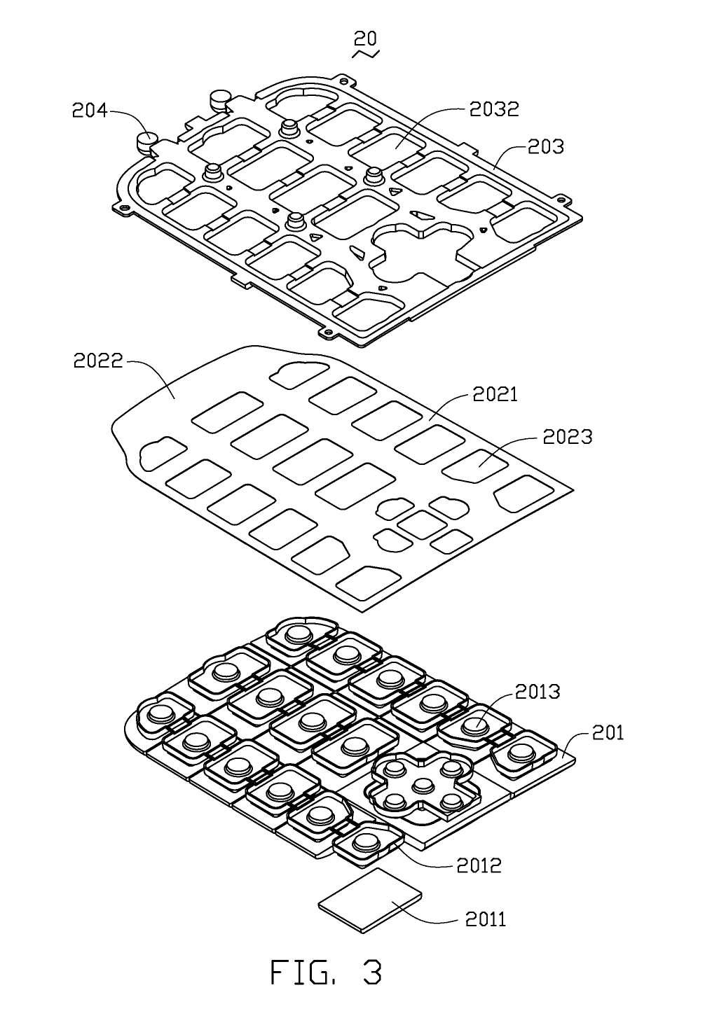

Referring further to FIGS. 2 and 3, the keypad assembly 20 includes a keypad 205, a light-guiding board 203, two light-emitting sources 204, and a light-shielding member 202.

The keypad 205 includes a plurality of key buttons 201 formed therewith, each of which includes a cover 2011, a main body 2012, and a protruding portion 2013. The key buttons 201 are arranged and distributed separately and in a certain order.

The cover 2011 of the key button, which is configured for accommodating the main body 2012 therein, is generally a hollow cube with an open end and a close end. The main body 2012 has an attaching surface 2014 (e.g., adhering surface) formed thereon. The cover 2011 is attached (e.g., adhered) with the main body 2012 and accommodates the main body 2012 therein. The protruding portion 2013 is formed on the main body 2012 opposite to the attaching surface 2014.

The light-shielding member 202 (e.g., a lighttight film) has roughly the same size and shape as that of the keypad 205. The light-shielding member 202 is disposed between the keypad 205 and the light-guiding board 203. The light-shielding member 202 includes a main portion 2021 and an extending portion 2022. The extending portion 2022 extends from one end of the main portion 2021. The main portion 2021 of the light-shielding member 202 has a plurality of through grooves 2023 defined therethrough respectively corresponding with the key buttons 201.

The light-guiding board 203 has substantially the same size and shape as that of the keypad 205. The light-guiding board 203 includes a second peripheral wall 2051 corresponding with a first peripheral wall 2051 of the keypad 205. The two light-emitting sources 204 (e.g., light emitting diodes) are disposed on a printed circuit board (not shown) and are proximate to the second peripheral wall 2051 of the light-guiding board 203 and aligned with the light-guiding board 203. The two light-emitting sources 204 are oriented toward a same side of the light-guiding board 203 and configured to be shielded by the extending portion 2021 of the light-shielding member 202.

The light-guiding board 203 further has a plurality of through apertures 2032 defined therethrough respectively corresponding with the key buttons 201.

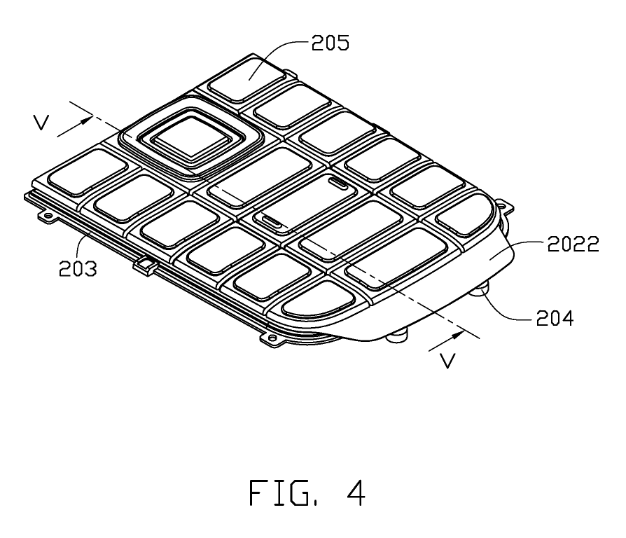

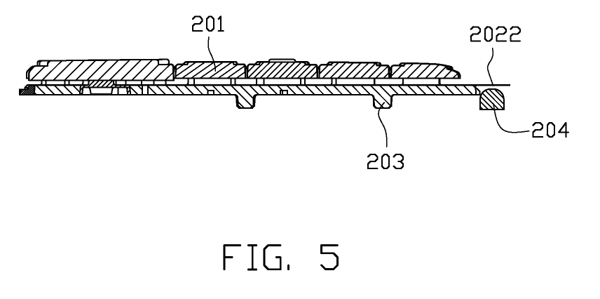

Referring also to FIGS. 4 and 5, as assembled, the key buttons 201 of the keypad 205 respectively engage through the through grooves 2023 and the through apertures 2032. In this case, the light-shielding member 202 is located between the keypad 205 and the light-guiding board 203. The extending portion 2022 of the light-shielding member 202 shields the two light-emitting sources 204. Thus, in use, light emitted from the light-emitting sources 204 can either be guided by the light-guiding board 203 or be shielded by the extending portion 2021. More specifically, the main portion 2021 allows light emitted from the light-emitting source through the through apertures 2032 of the light-guiding board 203 and the through grooves 2023 of the light-shielding member 202, thereby illuminating the keypad assembly 20. Further, the extending portion 2021 shields emitted light diffusing toward the first peripheral wall 2051 of the keypad 205.

It is to be understood that another alternative light-shielding member can include a main portion 2021 and at least two extending portions 2022. The at least two extending portions 2022 can extend from one same end or distinct ends of the main portion 2021, respectively. As such, the light-guiding board 203 can have at least one light-emitting source 204 disposed thereon. The at least one light-emitting source 204 is configured to be shielded by the extending portions 2022.

One main advantage of the present embodiments embodies as follows. The main portion 2021 of the light-shielding member 202 allows light to penetrate through the through apertures 2032 of the light-guiding board 203 and the through grooves 2023 of the light-shielding member 202 to illuminate the keypad assembly 20. As such, the extending portion 2022 shields light emitted from the two light-emitting sources 204 diffusing toward the first peripheral wall 2051 of the keypad 205. Thus, even if a minor gap is formed between the first peripheral wall 2051 of the keypad assembly 20 and an inner wall of the housing 30 during assembly, the extending portion 2022 shields light diffusing toward the minor gap. Correspondingly, light emitted from the light-emitting sources 204 can be guided to illuminate the keypad assembly 20 alone.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A keypad assembly for use in a portable electronic device, comprising:
a keypad comprising a first peripheral wall;
a light-guiding board comprising a second peripheral wall, the second peripheral wall corresponding with the first peripheral wall;
at least one light-emitting source disposed proximate to the second peripheral wall of the light-guiding board and respectively aligned with the light-guiding board; and
a light-shielding member disposed between the keypad and the light-guiding board, the light-shielding member comprising a main portion and at least one extending portion, the at least one extending portion extending from the main portion, the main portion configured for allowing light emitted from the light-emitting source to penetrate through the light-guiding board to illuminate the keypad assembly, and the at least one extending portion configured for shielding light emitted from the at least one light-emitting source and diffusing toward the first peripheral wall.

2. The keypad assembly as claimed in claim 1, wherein the at least one light-emitting source is two light-emitting sources, the two light-emitting sources being disposed on a side of the light-guiding board, and the at least one extending portion being one extending portion.

3. The keypad assembly as claimed in claim 1, wherein the keypad comprises a plurality of key buttons formed therewith, the main portion of the light-shielding member having a plurality of through grooves defined therethrough respectively corresponding to the key buttons, and the light-guiding board having a plurality of through apertures defined therethrough respectively corresponding to the key buttons.

4. The keypad assembly as claimed in claim 3, wherein the key buttons respectively engage through the through grooves and the through apertures.

5. The keypad assembly as claimed in claim 3, wherein each key button comprises a cover, a main body, and a protruding portion, the main body having an attaching surface formed thereon, the cover attached with the main body, and the protruding portion formed on the main body opposite to the attaching surface.

6. The keypad assembly as claimed in claim 5, wherein the cover is adhered with the main body.

7. The keypad assembly as claimed in claim 1, wherein the light-shielding member is a lighttight film.

8. A portable electronic device, comprising:
a housing; and
a keypad assembly assembled with the housing, comprising:
a keypad comprising a first peripheral wall;
a light-guiding board comprising a second peripheral wall, the second peripheral wall corresponding with the first peripheral wall;
at least one light-emitting source disposed proximate to the peripheral wall of the light-guiding board and respectively aligned with the light-guiding board; and
a light-shielding member disposed between the keypad and the light-guiding board, the light-shielding member comprising a main portion and at least one extending portion, the at least one extending portion extending from the main portion, the main portion configured for allowing light emitted from the light-emitting source to penetrate through the light-guiding board to illuminate the keypad assembly, and the at least one extending portion configured for shielding light emitted from the at least one light-emitting source and diffusing toward the first peripheral wall.

9. The portable electronic device as claimed in claim 8, wherein the at least one light-emitting source is two light-emitting sources, the two light-emitting sources being disposed on a same sidewall of the light-guiding board, and the at least one extending portion being one extending portion.

10. The portable electronic device as claimed in claim 8, wherein the keypad comprises a plurality of key buttons formed therewith, the main portion of the light-shielding member having a plurality of through grooves defined therethrough respectively corresponding to the key buttons, and the light-guiding board having a plurality of through apertures defined therethrough respectively corresponding to the key buttons.

11. The portable electronic device as claimed in claim 10, wherein the key buttons respectively engage through the through grooves and the through apertures.

12. The portable electronic device as claimed in claim 8, wherein the light-shielding member is a lighttight film.
